(19) United States
(12) Patent Application Publication
(10) Pub. No.: US 2009/0289899 A1
(43) Pub. Date: Nov. 26, 2009

(54) KEYPAD MODULE FOR CHARACTER INPUT, ELECTRONIC DEVICES UTILIZING THE SAME, AND METHOD THEREOF

(75) Inventor: HUNG-CHEN WU, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignee: CHI MEI COMMUNICATION SYSTEMS, INC., Tu-Cheng City, Taipei County (TW)

(21) Appl. No.: 12/199,898

(22) Filed: Aug. 28, 2008

(30) Foreign Application Priority Data
May 21, 2008 (CN) 200810301706.6

(51) Int. Cl. G06F 3/02; H03K 17/94

(52) U.S. Cl. 345/169; 341/34

(57) ABSTRACT

A keypad module (114) including at least one key (20) is described. The key includes a keycap (24), a rocker (28) and a plurality of domes (32). The rocker includes a central shaft (281 ) and extending portions (282) extending from the central shaft. A top (2811a) of the central shaft joins with the keycap. The domes are located on a circuit board (50) corresponding to the central shaft and the extending portions. The corresponding dome is activated when the central shaft or the extending portions receive an external force.

### BACKGROUND

1. Field of the Invention

The present invention relates to data input, and particularly to a keypad module, electronic devices equipped with the keypad module, and a method for character input utilizing the keypad module.

2. Discussion of the Related Art

With rapid developments in information technology, electronic devices such as cellular phones, personal digital assistant (PDA), and others are gaining popularity. Consequently, users demand more than simply basic functions such as placing/answering phone calls and sending/receiving short messages, expecting the capability to access the Internet and send/receive email. Such functions require a method for efficient character input for the portable electronic devices.

Accordingly, a PDA or mobile phone 10 is often equipped with a QWERTY keypad 12 as shown in FIG. 7. English characters are arranged on a surface of the QWERTY keypad 12, requiring that the overall size of the mobile phone 10 be sufficient to provide the arrangement. However, such keypads may compromise demand for lighter and thinner electronic devices. In addition, key separation on the keypad is minimal, increasing likelihood of erroneous character input.

Therefore, there is room for improvement within the art.

### BRIEF DESCRIPTION OF THE DRAWINGS

Many aspects of the keypad module can be better understood with reference to the following drawings. The components in the drawings are not necessarily to scale, the emphasis instead being placed upon clearly illustrating the principles of the present keypad module. Moreover, in the drawings, like reference numerals designate corresponding parts throughout the several views.

FIG. 1 is an isometric, assembled view of an electronic device equipped with a keypad module according to an exemplary embodiment.

FIG. 2 is an exploded view of the exemplary keypad module of FIG. 1.

FIG. 3 is a cross-section of the assembled keypad module of FIG. 2.

FIG. 4 is an isometric, assembled view of the keypad module of FIG. 2.

FIG. 5 is a flowchart of a method for character input using the electronic device of FIG. 1.

FIG. 6 is an isometric view of the electronic device of FIG. 1 when a key of the keypad module is pressed.

FIG. 7 is an isometric view of an electronic device equipped with the typical keypad module.

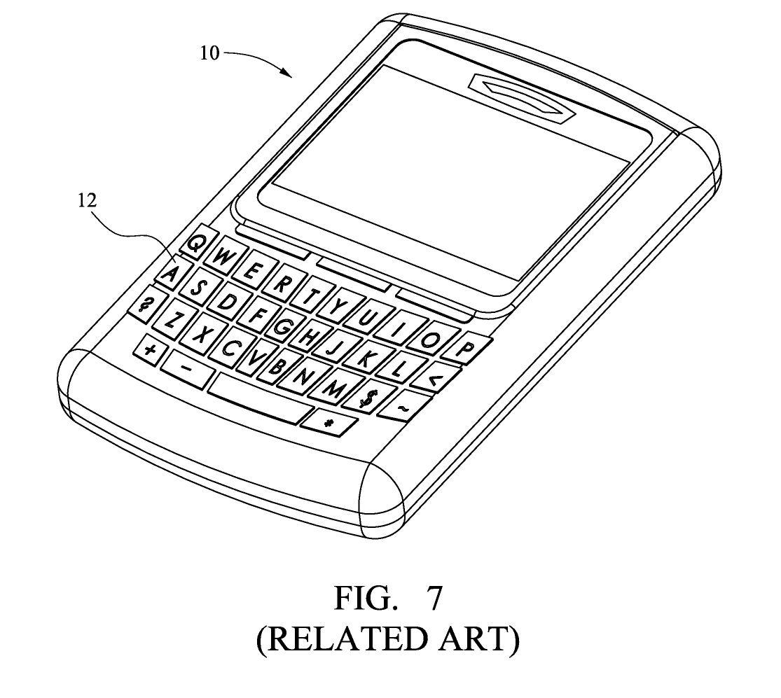

### DETAILED DESCRIPTION OF THE EMBODIMENTS

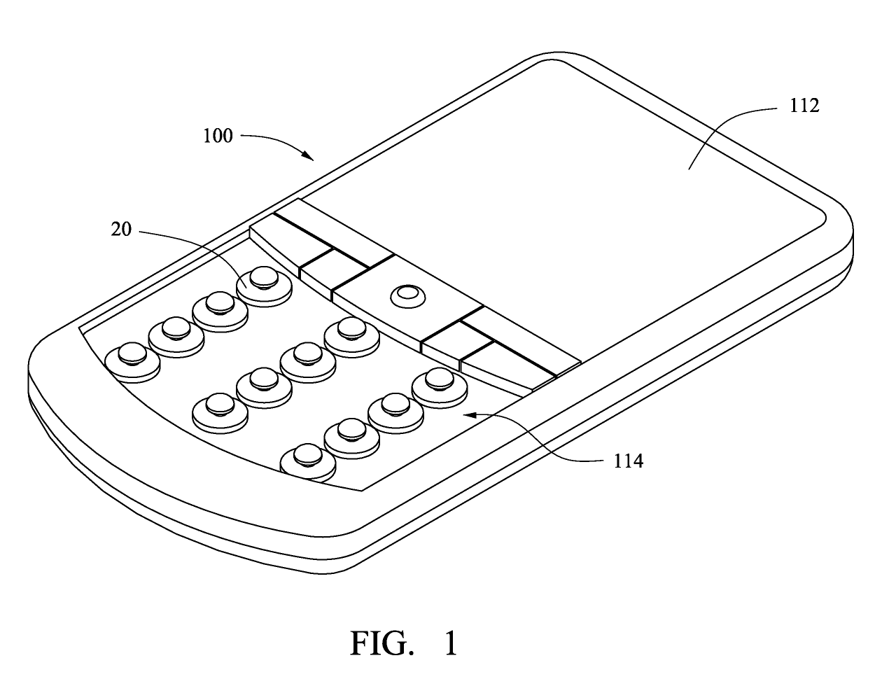

FIG. 1 shows a mobile phone 100 equipped with a display 112 and a keypad module 114. The keypad module 114 has at least one key 20 by which users may input characters then shown on the display 112. While the mobile phone 100 is taken here as an exemplary application for the purposes of describing details of the keypad module 114, in alternative embodiments, the mobile phone 100 can be replaced by other portable electronic devices, such as a personal digital assistant (PDA), although the disclosure is not limited thereto.

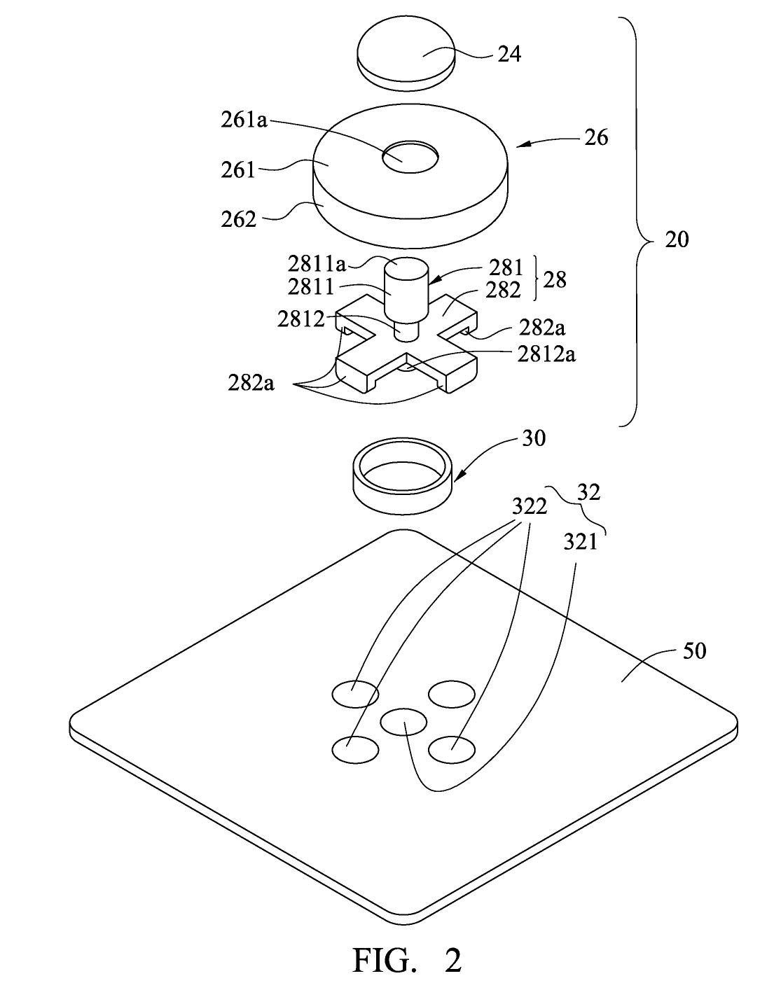

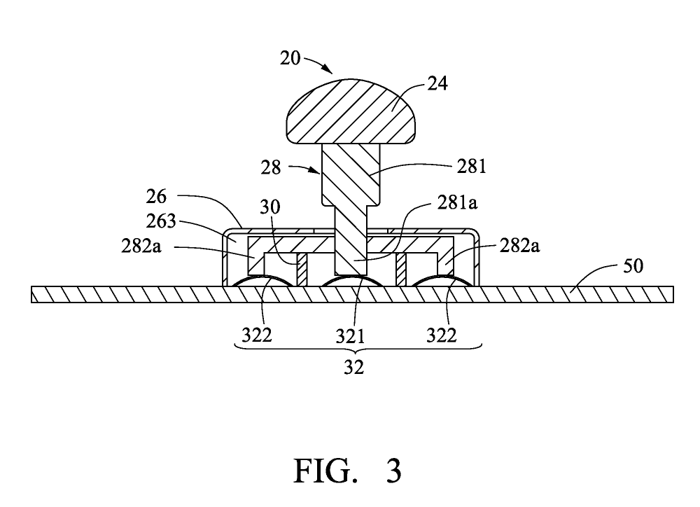

Referring to FIGS. 2 and 3, each key 20 includes a keycap 24, a cover 26, a rocker 28, a supporting member 30 and a plurality of domes 32.

The keycap 24 receives external force delivered by user contact therewith. In the exemplary embodiment, the keycap 24 is substantially semi-spherical. In alternative embodiments, the keycap 32 may have other geometric shapes. The keycap 24 may be made from a plastic material.

The cover 26 includes a top surface 261 and a peripheral wall 262 extending from edges of the top surface 261. The top surface 261 defines a circular hole 261a in a central area thereof. The peripheral wall 262 is substantially perpendicular to the top surface 261. The cover 26 is made from a metallic material. The peripheral wall 262 with the top surface 261 surrounds a receiving cavity 263 for protecting the keys 20 from contaminants and moisture, increasing the lifetime thereof.

The rocker 28 includes a central shaft 281 and extending portions 282 extending therefrom. The central shaft 281 includes a head portion 2811 and a neck portion 2812. The diameter of head portion 2811 exceeds the diameter of the neck portion 2812.

As shown in FIG. 3, the diameter of the head portion 2811 is less than the diameter of the hole 261a. Therefore, the head portion 2811 passes through the hole 261a and a top 2811a of the head portion 2811 abuts the keycap 24.

The neck portion 2812 joins with the extending portions 282 and downwardly protrudes from the extending portions 282 to form a central pillar 2812a. In alternative embodiments, the neck portion 2812 may be integrally formed with the extending portions 282.

In the exemplary embodiments, the extending portions 282 substantially form a cross, providing four end pillars 282a on four ends thereof. In alternative embodiments, the extending portions 282 may be of other geometric shapes and a plurality of end pillars 282a provided.

The supporting member 30 is a substantially annular frame made from a plastic material. The supporting member 30 is arranged below the extending portions 282, supporting the rocker 28. The diameter of the supporting member 30 is less than the distance between opposing end pillars 282a.

The domes 32 are made from a metallic material, such as stainless steel or copper, and arranged on a circuit board 50. The domes 32 include a central dome 321 corresponding to the central pillar 2812a and four end domes 322 corresponding to the end pillars 282a.

Referring to FIG.3, a cross-section of the keypad module 114 is shown. The central dome 321 is arranged below the central pillar 2812a and the end domes 322 respectively correspond to the corresponding end pillar 282a. The supporting member 30 is positioned below the extending portions 282, keeping the rocker 28 in position when the keycap 24 is not subjected to an external force. The receiving cavity 263 of the cover 26 receives the extending portions 282 and protects the domes 32 and the circuit board 50 from contamination. In addition, the cover 26 also prevents over-extension of the central shaft 281.

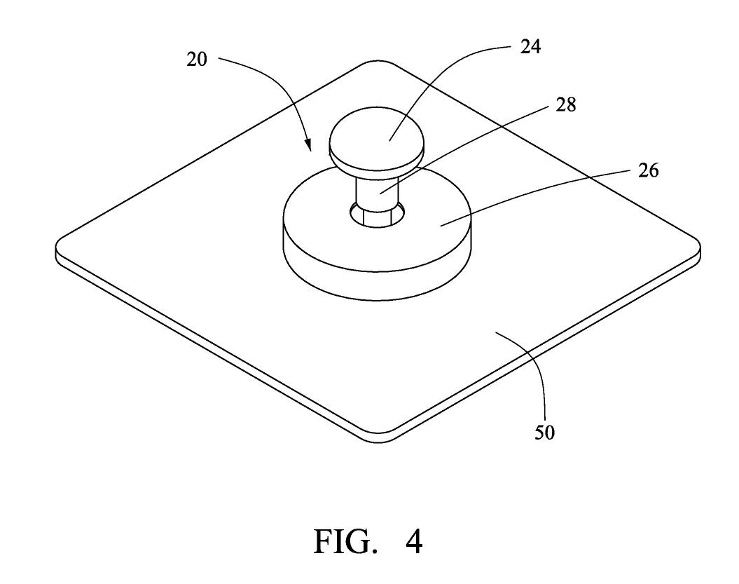

FIG. 4 shows an assembled key 20 of the keypad module 114 arranged on the circuit board 50 having a plurality of switches (not shown) arranged thereon in positions corresponding to domes 32. Keycap 24 can be pressed straight downward or toward respective ends of the extending portions 282 by the central shaft 281. Referring to FIG. 3, when downward external force is applied to the keycap 24, the central shaft 281 and the central pillar 2812a move downward accordingly to activate the central dome 321. The central dome 321 further triggers corresponding electrical switches on the circuit board 50.

Similarly, in the exemplary embodiment, when external force on the keycap 24 moves the central shaft 281 in a front, back, right, or left direction, the central shaft 281 moves accordingly, to press the corresponding end pillar 282a downward. In this way, the corresponding end pillar 282a also moves downward to activate the end domes 322, further triggering corresponding electrical switches on the circuit board 50.

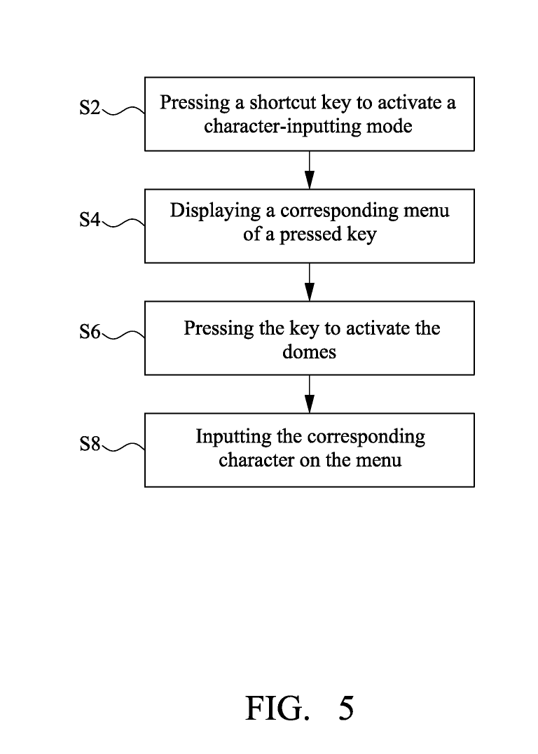

Referring to FIG. 5, a method for character input using the mobile phone 100 is as follows. In step S2, a shortcut key of the mobile phone 100 activates a character-input mode, which may alternatively be activated by selection of an option from menus shown on the display 112. In alternative embodiments, the shortcut key may again switch to other character-input methods.

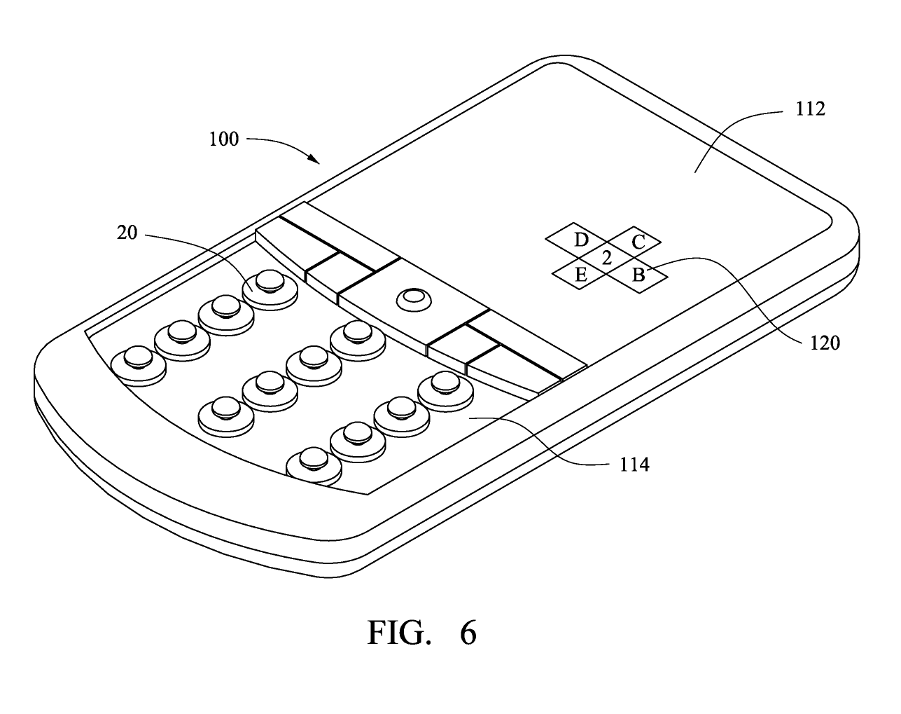

In step S4, a corresponding menu 120 of a pressed key 20 is shown on the display 112. Also referring to FIG. 6, the corresponding menu 120 is shown on the display 112 when one of the keys 20 is pressed. In the exemplary embodiment, the menu 120 includes five options and forms a cross. The central region of the menu 120 represents the digit of the key 20, and the other four options respectively represent English characters.

In step S6, the key 20 activates domes 321, 322 on the circuit board 50, 321 by downward force, and the end domes 322 respectively by force on key 20 in lateral directions. Each central dome 321 and end dome 322 correspond to one option of the menu 120. In step S8, the corresponding digit or English character is input to the mobile phone 100. For example, the digit “2” is input to the mobile phone 1 corresponding to downward force on the key 20. The character “B” is input to the mobile phone 100 corresponding to force on key 20 moving central shaft 281 in a left direction.

It is believed that the present embodiments and their advantages will be understood from the foregoing description, and it will be apparent that various changes may be made thereto without departing from the spirit and scope of the invention or sacrificing all of its material advantages, the examples hereinbefore described merely being preferred or exemplary embodiments of the invention.

What is claimed is:

1. A keypad module including at least one key, the key comprising:
a keycap;
a rocker joined with the keycap, the rocker comprising a central shaft and a plurality of extending portions extending therefrom;
a plurality of domes located on a circuit board corresponding to the central shaft and the extending portions; and
wherein a corresponding dome is activated when the central shaft or the extending portions receive an external force.

2. The keypad module as claimed in claim 1, wherein the key further comprises a cover with a top surface and a peripheral wall extending from edges of the top surface.

3. The keypad module as claimed in claim 2, wherein the top surface defines a hole in a central area of the top surface through which the central shaft passes to join with the keycap.

4. The keypad module as claimed in claim 1, wherein the central shaft includes a head potion and a neck portion, the diameter of the head portion exceeding the diameter of the neck portion.

5. The keypad module as claimed in claim 4, wherein the neck portion joins with the extending portions and protrudes therefrom to form a central pillar, and the extending portions form a plurality of end pillars on ends thereof.

6. The keypad module as claimed in claim 1, wherein the key further comprises a supporting member located below the extending portions of the rocker, supporting the rocker.

7. The keypad module as claimed in claim 1, wherein the extending portions comprise a plurality of ends, the distance between opposing ends exceeding the diameter of the supporting member.

8. The keypad module as claimed in claim 1, wherein the cover is made from a metallic material.

9. The keypad module as claimed in claim 1, wherein the keycap and the rocker are made from a plastic material.

10. An electronic device comprising a circuit board and a keypad module, the circuit board comprising a plurality of switches arranged thereon, the keypad module comprising at least one key, the key comprising:
a keycap;
a rocker joined with the keycap, the rocker comprising a central shaft and a plurality of extending portions extending therefrom;
a plurality of domes on a circuit board corresponding to the central shaft and the extending portions; and
wherein a corresponding dome triggers electrical switches on the circuit board when the central shaft or the extending portions receive an external force.

11. The electronic device as claimed in claim 10, wherein the key further comprises a cover with a top surface and a peripheral wall extending from edges thereof.

12. The electronic device as claimed in claim 11, wherein the top surface defines a hole in a central area of the top surface, through which the central shaft passes to join with the keycap.

13. The electronic device as claimed in claim 10, wherein the central shaft includes a head portion and a neck portion, the diameter of the neck portion being less than the diameter of the head portion.

14. The electronic device as claimed in claim 13, wherein the neck portion joins with the extending portions and protrudes therefrom to form a central pillar, and the extending portions form a plurality of end pillars on ends of the extending portions.

15. The electronic device as claimed in claim 10, wherein the key further comprises a supporting member below the extending portions of the rocker, providing support thereto.

16. The electronic device as claimed in claim 10, wherein the extending portions comprise a plurality of ends, the distance between opposing ends exceeding the diameter of the supporting member.

17. A method for character input for an electronic device, the electronic device comprising a display, a circuit board with a plurality of switches and a keypad module with at least one key, the method comprising:
activating a character-input mode;
applying external force to the at least one key and displaying a menu corresponding thereto;
applying external force to at least one key in a downward direction to trigger a corresponding switch on the circuit board by a central dome of the key or applying external force to a central shaft of at least one key in a front, back, right, or left direction to trigger corresponding switches on the circuit board, wherein each dome corresponds to an option on the corresponding menu; and
inputting the corresponding digits or characters in accordance with the activated domes.

18. The method as claimed in claim 17, wherein the character-input mode is activated by a shortcut key.

19. The method as claimed in claim 18, wherein the shortcut key is activated again to switch to another character-input method.
